(19) United States
(12) Patent Application Publication
(10) Pub. No.: US 2008/0088378 A1
(43) Pub. Date: Apr. 17, 2008

(54) PHASE LOCKED LOOP HAVING CONTINUOUS BANK CALIBRATION UNIT AND METHOD OF PREVENTING UNLOCKING OF PLL

(75) Inventors: Hyun Ji SONG, Gyeonggi-do (KR); Kyung Lok KIM, Seoul (KR); Kyoo Hyun LIM, Gyeonggi-do (KR)

Correspondence Address: CANTOR COLBURN, LLP, 20 Church Street, 22nd Floor, Hartford, CT, 06103, US

(73) Assignee: FCI INC., Gyeonggi-do (KR)

(21) Appl. No.: 11/868,657

(22) Filed: Oct. 8, 2007

(30) Foreign Application Priority Data
Oct. 12, 2006 (KR) 10-2006-0099236

(51) Int. Cl. H03L 7/099; H03L 7/08

(52) U.S. Cl. 331/10

(57) ABSTRACT

A phase locked loop (PLL) having a continuous bank calibration unit and a method of preventing unlocking of the PLL are provided. The PLL includes a main circuit, a voltage controlled oscillator (VCO), and a continuous bank calibration unit. The main circuit outputs a control voltage in response to an external clock signal and an oscillating signal. The VCO outputs the oscillating signal in response to the control voltage and the bank calibration signal. The continuous bank calibration unit compares the received control voltage with a window voltage having at least two comparison values to output the bank calibration signal. In the PLL having a continuous bank calibration unit, although the control voltage varies with external factors such as temperature, the bank of the VCO is immediately and suitably calibrated to prevent unlocking of the PLL, so that it is possible to Improve an output characteristic of the VCO.

This application claims priority to Korean Patent Application No. 10-2006-0099236, filed on Oct. 12, 2008, all the benefits accruing therefrom under 35 U.S.C. §119, the contents of which in their entirety are incorporated herein by reference.

### BACKGROUND OF THE INVENTION

1. Field of the Invention

The present invention relates to a phase locked loop (PLL) and, more particularly, to a PLL having a continuous bank calibration unit capable of preventing unlocking of PLL caused from external factors such as temperature and a method of preventing unlocking of PLL.

2. Description of the Related Art

FIG. 1 is a circuit view illustrating a conventional PLL.

Referring to FIG. 1 the conventional PLL 10 includes a main circuit 11 which outputs a control voltage Vcon in response to an external clock signal Ext_clk and an oscillating signal Vco_out and a voltage controlled oscillator (VOC) 12 which outputs the oscillating signal Vco_out having a frequency corresponding to the control voltage Vcon.

FIG. 2 is a graph illustrating a relationship between a frequency range of the oscillating signal and a control voltage in a case where the VCO 12 is not provided with a bank.

Referring to FIG. 2, in a case where the VCO 12 is not provided with a bank, a relation ship between a control voltage Vcon and a frequency F of an oscillating signal Vco_out which is output in response to the control voltage Vcon is expressed by an equation of a straight line, and its slope is a VCO gain Kvco. The VCO gain Kvco can be expressed by Equation 1.

[Equation 1]

$$Kvco = \frac{Δ F}{Δ Vcon}$$

When the frequency range Δ F that is to be covered by the output Vco_out of the VCO 12 is wide, the slop Kvco is inevitably increased, so that the VCO gain Kvco is increased. If the VCO gain Kvco is increased, a phase noise characteristic of a system is deteriorated.

FIG. 3 is a graph illustrating a relationship between a frequency range of the oscillating signal and a control voltage in a case where the VCO 12 is provided with a bank.

Referring to FIG. 3, the frequency range that is to be covered by the output Vco_out of the VCO 12 is divided into several frequency ranges Δ F0, Δ F1, Δ F2, . . . , and the frequency ranges are separately covered by banks allocated to the frequency ranges. For example, a first frequency range Δ F0 is covered by a first bank Bank0, a second frequency range Δ F1 is covered by a second bank Bank1, and a third frequency range Δ F2 is covered by a third bank Bank2. Even in case of a VCO 12 having a low VCO gain characteristic, if the associated bank is modified: a wide frequency range can be covered. As a result, the phase noise characteristic of the system can be improved.

However, in the conventional PLL 10, after an optimal bank is initially determined, the bank is maintained in the same state. Therefore, the conventional PLL can be operated in the only allowable frequency range associated with the bank.

Although the system is initially set to be in an optimal condition, the system needs to be adapted to a change in external factors such as temperature. As the system is used, a temperature of system or a temperature of environment is changed. In this case, characteristics of the main circuit 11 and the VCO 12 of the system are changed, so that the control voltage Vcon is changed.

If the system cannot cope with the aforementioned change, the control voltage Vcon may be out of a predetermined allowable range which is initially set, so that the PLL 10 may be unlocked.

### SUMMARY OF THE INVENTION

The present invention provides a phase looked loop (PLL) having a continuous bank calibration unit capable of preventing unlocking of the PLL caused from external factors such as temperature,

The present invention provides a method of preventing unlocking of a PLL caused from external factors such as temperature.

According to an aspect of the present invention, there is provided a phase locked loop (PLL) comprising a main circuit, a voltage controlled oscillator (VCO), and a continuous bank calibration unit. The main circuit outputs a control voltage in response to an external clock signal and an oscillating signal. The VCO outputs the oscillating signal in response to the control voltage and the bank calibration signal. The continuous bank calibration unit compares the received control voltage with a window voltage having at least two comparison values to output the bank calibration signal.

According to another aspect of the present invention, there is provided a method of preventing unlocking of a PLL, the method comprising a current bank setting step, a comparison signal outputting step, a bank calibration signal outputting step, and a repetition step, in the current bank setting step, a current bank is set In comparison signal outputting step, a control voltage output from a main circuit is compared with a window voltage having at least two comparison values, and a determined comparison signal is output. In the bank calibration signal outputting step, a bank calibration signal is output in response to the comparison signal. In the repetition step, the comparison signal outputting step and the bank calibration signal outputting step are repeated.

According to still another aspect of the present Invention, there is provided a method of preventing unlocking of a PLL, the method comprising a monitoring step, a bank calibration determining step, and a repetition step. In the monitoring step, it is monitored whether or not a control voltage output in response to an external clock signal and oscillating signal is in an allowable range that is a window voltage. In the bank calibration determining step, it is determined based on a result of the monitoring whether or not a bank is needed to be calibrated, and a bank calibration signal is output. In the repetition step, the monitoring step and the bank calibration determining step are repeated,

### BRIEF DESCRIPTION OF THE DRAWINGS

The above and other features and advantages of the present invention will become more apparent by describing in detail exemplary embodiments thereof with reference to the attached drawings in which:

FIG. 1 is a circuit view illustrating a conventional PLL;

FIG. 2 Is a graph illustrating a relationship between a frequency range of an oscillating signal and a control voltage in a case where VCO is not provided with a bank;

FIG. 3 is a graph illustrating a relationship between a frequency range of an oscillating signal and a control voltage in a case where VCO is provided with a bank;

FIG. 4 is a circuit view illustrating a PLL having a continuous bank calibration unit according to an embodiment of the present invention; and

FIG. 5 is a view illustrating operations of the continuous bank calibration unit of FIG. 4.

FIG. 6 is a flowchart illustrating a method of preventing unlocking of a PLL according to an embodiment of the present invention.

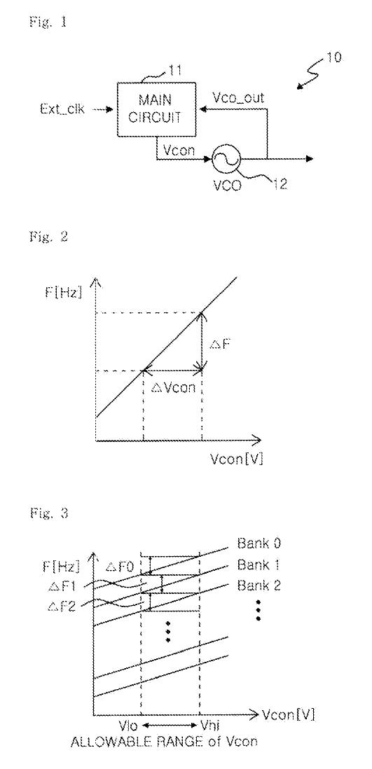

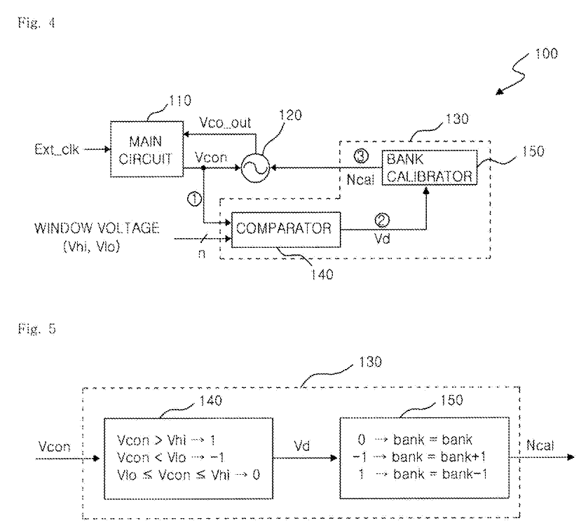

### DETAILED DESCRIPTION OF THE INVENTION

Hereinafter, exemplary embodiments of the present invention are described in detail with reference to the accompanying drawings.

FIG. 4 is a circuit view illustrating a phase locked loop (PLL) having a continuous hank calibration unit according to an embodiment of the present invention.

Referring to FIG. 4, the PLL 100 according to the embodiment of the present invention includes a main circuit 110, a voltage controlled oscillator (VCO) 120, and a continuous bank calibration unit 130.

The main circuit 110 outputs a control voltage Vcon in response to an external clock signal Ext_clk and an oscillating signal Vco_out. The VCO 120 includes a plurality of banks (not shown) which cover different frequency ranges. The VCO 120 outputs oscillating signal Vco_out in response to a control voltage Vcon and a bank calibration signal Ncal. Each bank (not shown) Includes at least one capacitor. The banks are designated with corresponding bank numbers.

The continuous bank calibration unit 130 compares the control voltage Vcon received from the main circuit 110 with a window voltage to output the bank, calibration signal Ncal. For the comparing operation, the continuous bank calibration unit 130 includes a comparator 140 and a bank calibrator 150. The window voltage has an upper comparison value Vhi and a lower comparison value Vlo. In addition, the window voltage may have the more comparison values.

The comparator 140 continuously receives as an input the control voltage Vcon from the main circuit 110 and compares the control voltage Vcon with the window voltage to output a comparison signal Vd.

The bank calibrator 150 outputs the bank calibration signal Ncal in response to the comparison signal Vd output from the comparator 140.

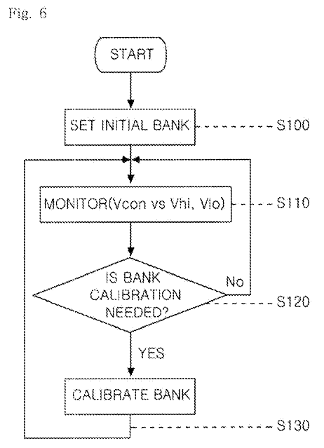

FIG. 5 is a view illustrating operations of the continuous bank calibration unit 130.

Referring to FIG. 5, the comparator 140 receives the control voltage Vcon output from the main circuit 110 and compares the control voltage Vcon with the upper comparison value Vhi and the lower comparison value Vlo.

The results of comparison of the control voltage Vcon with the upper and lower comparison values Vhi and Vlo are divided into the following three cases.

First Case: the control voltage Vcon is larger than the upper comparison value Vhi, (Vcon>Vhi).

Second Case: the control voltage Vcon is smaller than the lower comparison value Vlo, (Vcon<Vlo).

Third Case, the control voltage Vcon is in a range between the upper comparison value Vhi and the lower comparison value Vlo, (Vlo≦Vcon≦Vhi).

In addition, the third case includes a case where the control voltage Vcon Is smaller than the upper comparison value Vhi and larger than the lower comparison value Vlo (Vlo<Vcon<Vhi) and a case where the control voltage Vcon is equal to the upper comparison value Vhi or the lower comparison value Vlo (Vcon=Vlo, Vcon=Vhi).

The comparator 140 outputs to the bank calibrator 150 the different comparison signals Vd corresponding to the three results of comparison.

In the third case where the control voltage Vcon is in a range between the upper comparison value Vhi and the lower comparison value Vlo (Vlo≦Vcon≦Vhi), the hank calibrator 150 receives the comparison signal Vd corresponding to the result of comparison from the comparator 140 and outputs the bank calibration signal Ncal indicating that the current bank is to be maintained.

In the first case where the control voltage Vcon is larger than the upper comparison value Vhi (Vcon>Vhi) or the second case where the control voltage Vcon is smaller than the lower comparison value Vlo (Vcon<Vlo), the bank calibrator 150 receives the comparison signals Vd corresponding to the results of comparison from the comparator 140 and outputs the bank calibration signals Ncal indicating that the current bank is to be calibrated.

Referring to the FIG. 5, in the first case where the control voltage Vcon is larger than the upper comparison value Vhi (Vcon>Vhi), the comparator 140 outputs the comparison signal Vd having a value of ‘1’. In the second case where the control voltage Vcon is smaller than the upper comparison value Vhi (Vcon<Vlo), the comparator 140 outputs the comparison signal Vd having a value of ‘−1’. in the third case where the control voltage Vcon is smaller than or equal to the upper comparison value Vhi and larger than or equal to the lower comparison value Vlo (Vlo≦Vcon≦Vhi), the comparator 140 outputs the comparison signal Vd having a value of ‘0’. Namely, the comparison signal Vd varies with the results of comparison of the comparator 140.

When receiving the comparison signal Vd having a value of ‘0’ from the comparator 140, the bank calibrator 150 outputs the bank calibration signal Ncal indicating that the current bank is to be maintained. When receiving the comparison signal Vd having a value of ‘1’ or from the comparator 140, the bank calibrator 150 outputs the bank calibration signal Ncal indicating that the current bank is to be calibrated.

As an example, the bank numbers may be designated in the order of from the bank covering high frequency to the bank covering low frequency. In this case, when the bank calibrator 150 receives the comparison signal Vd having a value of ‘1’, the bank calibrator 150 outputs the bank calibration signal Ncal indicating that the current bank is to be calibrated into a bank covering higher frequency (bank=bank−1). On the contrary, when the bank calibrator 150 receives the comparison signal Vd having a value of ‘−1’ the bank calibrator 150 outputs the bank calibration signal Ncal indicating that the current bank is to be calibrated into a bank covering lower frequency (bank=bank+1).

Namely, the bank calibration signals Nacl output from the bank calibrator 150 indicate that the current bank of the VCO 120 is to be maintained or calibrated into a different bank.

Now, operations of the PLL 100 having a continuous bank calibration unit according to the embodiment of the present invention are described with reference to FIGS. 4 and 5.

In the PLL illustrated in FIG. 4, when the control voltage Vcon is in a predetermined allowable range, the PLL 100 is initially set to an optimal bank corresponding to the allowable range.

When the control voltage Vcon is out of the allowable range due to a change of external environments, the PLL 100 that operates by using the initially-set optimal bank calibrates the bank according to the change of external environments. For the calibration, the control voltage Vcon is output from the main circuit 110 (\textcircled{1} in FIG. 4). The control voltage Vcon Is compared with the window voltages Vhi and Vlo, and the determined comparison signal Vd is output (\textcircled{2} in FIG. 4). In response to the comparison signal Vd, the bank calibration signal Nacl is output (\textcircled{3} in FIG. 4).

By repeatedly performing the comparison and calibration, although the control voltage Vcon is our of the allowable range due to external factors such as temperature, the bank can be immediately calibrated, so that the control voltage Vcon can be in the allowable range. Accordingly, the PLL 100 can be stably operated.

FIG. 6 is a flowchart illustrating a method of preventing unlocking of a PLL 100 according to an embodiment of the present invention.

Referring to FIG. 8, the method of preventing unlocking of the PLL 100 includes an initial bank setting step S100, a monitoring step S110, a bank calibration determining step S120, and a repetition step S130.

In the initial bank setting step S100, an initial bank is set so that a control voltage Vcon output in response to an external clock signal Ext_clk and an oscillating signal Vco_out is in a predetermined allowable range (in a range of window voltage). In the initial bank setting step, a binary searching algorithm may be used.

In the monitoring step S110, it is continuously monitored whether or not the control voltage Vcon output in response to the external clock signal Ext_clk and the oscillating signal Vco_out is in the predetermined allowable range after the initial bank setting step S100.

More specifically, in the monitoring step S110, the control voltage Vcon is compared with window voltage having at least two comparison values, for example, window voltage having upper and lower comparison values Vhi and Vlo, and the determined comparison signal Vd is output. An example of the comparison and the results of comparison is as follows.

As a result of comparison of the control voltage Vcon with upper comparison value Vhi, when the control voltage Vcon is larger than the upper comparison value Vhi (Vcon>Vhi), the corresponding comparison signal Vd is output.

As a result of comparison of the control voltage Vcon with the lower comparison value Vlo, when the control voltage Vcon is smaller than the lower comparison value Vlo (Vcon<Vlo), the corresponding comparison signal Vd is output.

As a result of comparison of the control voltage Vcon with the upper and lower comparison values Vhi and Vlo, when the control voltage Vcon is smaller than or equal to the upper comparison value Vhi and larger than or equal to the lower comparison value Vlo (Vlo≦Vcon≦Vhi), the corresponding comparison signal Vd is output.

In the bank calibration determining step S120, it is determined based on the result of the monitoring step S110 whether or not the bank calibration is needed, and the bank calibration signal Ncal is output.

The bank calibration signal Ncal is a signal indicating that the bank is to be calibrated or a signal indicating that the monitoring is to be performed without the calibration of bank.

When the control voltage Vcon is in the predetermined allowable range, that is, when the control voltage Vcon is smaller than or equal to the upper comparison value Vhi and larger than or equal to the lower comparison value Vlo, the bank calibration signal Ncal indicating that the bank is to be maintained is output.

On the contrary,, when the control voltage Vcon is not in the predetermined allowable range, that is, when the control voltage Vcon is larger that the upper comparison value Vhi or smaller than the lower comparison value Vlo, the bank calibration signal Nacl indicating that the bank is to be calibrated is output.

In the repetition step S130, the monitoring step S110 and the bank calibration determining step S120.

In a PLL having a continuous bank calibration unit according to the present invention, although a control voltage varies with external factors such as temperature, a bank of a VCO is immediately and suitably calibrated to prevent unlocking of the PLL, so that it is possible to improve an output characteristic of the VCO.

While the present invention has been particularly shown and described with reference to exemplary embodiments thereof, it will be understood by those skilled in the art that various changes in form and details may be made therein without departing from the spirit and scope of the present invention as defined by the appended claims.

What is claimed is:

1. A PLL (phase locked loop), comprising:
a main circuit which outputs a control voltage in response to an external clock signal and an oscillating signal;
a VCO (voltage controlled oscillator) which outputs the oscillating signal In response to the control voltage and a bank calibration signal; and
a continuous bank calibration unit which compares the received control voltage with a window voltage having at least two comparison values to output the bank calibration signal.

2. The PLL according to claim 1, wherein the continuous bank calibration unit comprises:
a comparator which compares the control voltage with the window voltage to output a determined comparison signal; and
a bank calibrator which outputs the bank calibration signal in response to the comparison signal.

3. The PLL according to claim 2, wherein the comparator continuously receives the control voltage as an input from the main circuit.

4. The PLL according to claim 2, wherein the window voltage has upper and lower comparison values.

5. The PLL according to claim 4,
wherein the comparator determines results of comparison including:
a result of comparison that the control voltage is larger than the upper comparison value (upper comparison value<control voltage);
a result of comparison that the control voltage is smaller than the lower comparison value (lower comparison value>control voltage); and
a result of comparison that the control voltage is smaller than or equal to the upper comparison value and larger than or equal to the lower comparison value (lower comparison value s control voltage≦upper comparison value), and
wherein the comparator outputs the different comparison signals corresponding to the results of comparison.

6. The PLL according to claim 5,
wherein, when the control voltage is smaller than or equal to the upper comparison value and larger than or equal to the lower comparison value, the bank calibrator outputs the bank calibration signal indicating that the bank is to be maintained, and
wherein, when the control voltage is larger than the upper comparison value or smaller than the lower comparison value, the bank calibrator outputs the bank calibration signal indicating that the bank is to be calibrated.

7. A method of preventing unlocking of the PLL according to claim 1 the method comprising steps of:
(a) setting a initial bank;
(b) comparing the control voltage output from the main circuit with the window voltage having at least two comparison values and outputting the determined comparison signal;
(c) outputting the bank calibration signal in response to the comparison signal; and
(d) repeating the step (b) and the step (c).

8. The method according to claim 7, wherein the window voltage has upper and lower comparison values.

9. The method according to claim 8, wherein the step (b) comprises steps of:
(b1) outputting the comparison signal corresponding to a result of comparison that the control voltage is larger than the upper comparison value;
(b2) outputting the comparison signal corresponding to a result of comparison that the control voltage is smaller than lower comparison value; and
(b3) outputting the comparison signal corresponding to a result of comparison except for the results of comparison corresponding to the step (b1) and the step (b2).

10. The method according to claim 9, wherein in the step (c), the bank calibration signal indicating that the bank is to be maintained or that the bank is to be calibrated is output in response to the comparison signal.

11. The method according to claim 10,
wherein in the step (c), when the control voltage is smaller than or equal to the upper comparison value and larger than or equal to the lower comparison value, the bank calibration signal indicating that the bank is to be maintained is output
wherein in the step (c), when the control voltage is larger than the upper comparison value or smaller than the lower comparison value, the bank calibration signal indicating that the bank Is to be calibrated is output.

12. A method of preventing unlocking of a PLL, the method comprising steps of:
(a) monitoring whether or not a control voltage in response to an external clock signal and an oscillating voltage is in a predetermined allowable range that is a window voltage;
(b) determining based on a result of the monitoring whether or not a bank is needed to be calibrated and outputting a bank calibration signal; and
(c) repeating the step (a) and the step (b).

13. The method according to claim 12, wherein In the step (a), the control voltage is compared with the window voltage having at least two comparison values, and a determined comparison signal is output.

14. The method according to claim 12,
wherein in the step (b), when the control voltage is in the allowable range, the bank calibration signal indicating that the bank is to be maintained is output, and
wherein in the step (b), when the control voltage is not in the allowable range, the bank calibration signal indicating that the bank is to be calibrated is output.

15. The method according to claim 13, wherein the window voltage has upper and lower comparison values.

16. The method according to claim 15, wherein the step (a) comprises steps of:
(a1) outputting the comparison signal corresponding to a result of comparison that the control voltage is larger than the upper comparison value;
(a2) outputting the comparison signal corresponding to a result of comparison that the control voltage is smaller than the lower comparison value; and
(a3) outputting the comparison signal corresponding to a result of comparison except for the results of comparison corresponding to the step (a1) and the step (a2).

17. The method according to claim 16,
wherein in the step (b), when the control voltage is smaller than or equal to the upper comparison value and larger than or equal to the lower comparison value, the bank calibration signal indicating that the bank is to be maintained Is output, and
wherein In the step (b), when the control voltage is larger than the upper comparison value or smaller than the lower comparison value, the bank calibration signal indicating that the bank is to be calibrated is output.
